(19) United States
(12) Patent Application Publication
(10) Pub. No.: US 2005/0151599 A1
(43) Pub. Date: Jul. 14, 2005

(54) Module for radio-frequency applications

(75) Inventors: Tatemi Ido, Tokyo (JP); Hiroshi Okabe, Tokyo (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 11/000,915

(22) Filed: Dec. 2, 2004

(30) Foreign Application Priority Data
Jan. 8, 2004 (JP) 2004-002595

(51) Int. Cl. H03H 9/72

(52) U.S. Cl. 333/133

(57) ABSTRACT

A radio frequency module with a SAW package mounted on the substrate is provided in a low profile structure also having excellent resistance to noise or in other words, electromagnetic compatibility even when a resin-sealed SAW package is utilized. Organic laminate of at least a single layer is used as the substrate of the radio frequency module, and a throughhole is formed on that organic laminate. The resin-sealed SAW package that encloses a flip-chip mounted SAW filter is mounted so that the ceramic substrate is positioned mainly outside the throughhole, and the SAW filter is positioned mainly inside the throughhole. A grounding conductor is formed on the rear side or the inner layer in the vicinity of the throughhole.

### CLAIM OF PRIORITY

The present invention claims priority from Japanese application JP 2004-002595 filed on Jan. 8, 2004, the content of which is hereby incorporated by reference into this application.

### FIELD OF THE INVENTION

The present invention relates to a radio frequency module for wireless communication devices such as wireless portable terminals typified by cellular phones.

### BACKGROUND OF THE INVENTION

In recent years, much progress has been made in making cellular phones more compact and with a lower profile. Along with this progress, many advances are also being made in making normally tall electronic components in particular such as antenna switches, power amplifier (hereafter called “PA”), and surface-acoustic-wave (hereafter called “SAW”) filters smaller (compact) and with a lower profile.

On the other hand, producing the radio frequency (hereafter called, “RF”) section of a cellular terminal which is a combination of multiple electronic components, requires sophisticated RF design and mounting technology. Therefore in order to simplify the development of the terminal, a unified type of RF module must be developed that integrates as many electronic components as possible into one module. For example, an RF module integrating an antenna switch and a SAW filter, and an RF module integrating an antenna switch in the PA have already been produced for the GSM (global system for mobile phone) system in Europe. An RF module that integrates an antenna switch, a SAW, a PA, and a transceiver RF-IC (RF-integrated circuit) into one package is also under study.

These types of RF modules are made by mounting semiconductor components (PA devices, RF-IC devices, and switch devices) and chip components (such as capacitors, resistors, inductors) on an RF substrate of ceramic or resin containing the RF circuit. On the other hand, an SAW filter chip should be mounted in a hermetic-sealed package because the operating principle of the SAW filter requires that a space be formed on the comb-shaped electrode to convey the surface-acoustic-wave and hermetic seal must be installed to prevent performance (properties) from deteriorating due to oxidation of the comb-shaped electrode. The most generally utilized method to obtain an RF module incorporating a SAW filter, is mounting an RF module made up of a SAW package with a hermetically sealed structure, onto an RF circuit substrate.

The SAW sealed package is configured as a ceramic package with metal cap as utilized in the related art. A SAW filter is mounted on this ceramic package and the metal cap fixed with solder, etc. To reduce the size, the SAW filter mainly used is a flip-chip connection type using a metallic bump, rather than the type that connects the SAW filter by a wire bonding connection. Moreover, to achieve an even smaller size and lower cost, a compact resin sealed package has been developed wherein the SAW filter is mounted as a flip-chip on a flat ceramic substrate and thermosetting resin injected into a part of the section between the ceramic substrate and the SAW filter to form a hollow sealed structure (see for example, patent document 1).

An example of an RF module on which a SAW package is mounted on the RF circuit substrate as described above is disclosed in patent document 2. Here, an antenna switch module is fabricated by mounting pin-switch devices, chip components, a SAW package and metal cap onto a ceramic multi-layered substrate.

An RF module with the RF-IC device, the PA device, a HEMT (High Electron Mobility Transistor) switch device mounted as a bare chip on the multi-layered resin substrate, the SAW package then mounted, and then all RF section components required for GSM/DCS (Digital Cellular System) dual-band sending and receiving then mounted, is disclosed in the non-patent document 1.
[Patent document 1] JP-A No. 8395/2003
[Patent document 2] JP-A No. 94410/2002

[Non-patent document 1] Publication issued by the IEEE Microwave Theory and Techniques Society (MTT-S) U.S.A. called the International Microwave Symposium Digest 2003, TH5B-4, Vol. 3, pp. 1707 to 1710.

### SUMMARY OF THE INVENTION

However, RF modules containing SAW filters have the problem of a high profile. This problem is caused by the fact that the height of the SAW package is 0.6 mm or more even when a low-profile (thin) SAW package sealed in resin is used and this height is large compared to the other chip components (size 0603, height 0.3 mm) and semiconductor devices that are mounted at the same time.

The height of multi-layered RF substrates utilized in antenna switch modules and unified RF modules is at least 0.4 mm. When covering the substrate mounted with the SAW package, chip component, and semiconductor components with a metal cap or a resin mold is attempted, the package thickness is a minimum of 1.2 mm which is high compared to other IC packages whose height of 1.0 mm or less.

Methods to reduce the height of the module where the SAW package is mounted include a method that forms a hole in the section of the metal cap covering the entire module where the SAW package is mounted; and a method that forms a depression (concave section) on the section of the RF substrate where the SAW package is mounted as disclosed in patent document 2. However, in the prior method, forming a large hole in the metal cap weakens the shield effect and has the further problem of making pickup difficult when mounting the module on the motherboard. In the latter method, the cost becomes drastically expensive when the RF substrate is resin and when the substrate is ceramic has the problem that the strength of the substrate deteriorates and cracks are prone to develop.

In many cases, these RF modules are sealed with resin mold such as epoxy resin over the entire surface of the substrate on which all components are mounted in order to increase the reliability of the module. However, when using SAW package sealed in resin, when the resin mold is applied, a high temperature and pressure act on the SAW package. This high temperature and pressure make the SAW package resin soften or melt, causing problems such as the hollow structure breaking, and the movement of the SAW filter causing defective electrical connections at the flip-chip contact points. Moreover, SAW packages sealed in resin have the problem that there is no ground conduction acting as an electromagnetic shield on the SAW filter side, so that the comb-shaped electrode of the SAW filter is easily susceptible to effects of electro-magnetic noise.

A first object of the present invention is to provide a low profile RF module on which is mounted a surface-acoustic-wave package.

A second object of the present invention is to avoid the problem that the resin of SAW package softens or melts during application of the over resin mold for the RF module, when using the resin-sealed SAW package in the low profile RF module.

A third object of the present invention is to provide a low profile RF module that is strongly resistant to electromagnetic noise even with a resin-sealed SAW package.

The above problems with the related art can be effectively resolved by forming a through-hole in the RF module substrate, and mounting SAW package on the module substrate so that at least a section of the sealed SAW is aligned at the inner section of the throughhole. In other words, the problem of the related art can be eliminated by mounting so that at least a section of the SAW package is inserted in the throughhole. A low profile RF module with SAW package is obtained since the height that the SAW package protrudes from the module substrate surface is reduced.

The SAW package for example may be fabricated by flip-chip mounting an SAW filter with a metallic bump on the ceramic substrate that has at least one ceramic layer and electrodes. Connection between the SAW module and the substrate of the RF module is easy in this case since the SAW package is mounted so that the SAW package substrate and a section of the electrode formed on that substrate are aligned at the outer section of the throughhole. The SAW package ceramic substrate for example is preferably set to a width larger than the width of the corresponding throughhole so that the SAW filter chip is at a position on an inside section of the throughhole and that the SAW package ceramic substrate is on an outside section of the throughhole. The electrodes formed on the ceramic substrate of the SAW package are preferably connected by soldering to a wiring path formed on the upper surface of the module substrate. The SAW package can in this way be mounted by the same process as the other components for mounting on the module substrate.

The SAW package is preferably fixed to the module substrate using adhesive (glue) while mounted so that at least a section of the package is positioned on the inner section of the throughhole. The SAW package can be fixed so that the throughhole is spatially blocked from the module substrate so that in particular, when applying resin mold to the RF module after mounting the resin-sealed SAW package, the mold resin that melts at high temperatures will not reach the SAW package resin. The problem of the SAW package resin softening or melting is therefore avoided.

Grounded conductors are preferably formed on the inner layer or the rear surface of the periphery of the throughhole formed in the module substrate in which at least a section of the SAW package is mounted. The grounded conductor encloses the SAW filter to function as an electromagnetic shield for the SAW filter. The grounded conductor in this way improves the SAW filter resistance to electromagnetic field noise when using a resin-sealed SAW package.

A part of the SAW package is placed in the throughhole formed on the RF module substrate so that the height the SAW package protrudes from the module substrate can be decreased and the present invention can therefore provide a low profile RF module on which is mounted an SAW package.

### BRIEF DESCRIPTION OF THE DRAWINGS

FIG. 1A is a plane view showing the first embodiment of the RF module of the present invention;

FIG. 1B is a cross sectional view taken along line A-A of FIG. 1A for describing the first embodiment;

FIG. 2A is a plane view of the vicinity of the SAW package in FIG. 1A;

FIG. 2B is a cross sectional view per line B-B of FIG. 2A;

FIG. 3A is a plane view for describing the mounted state of the RF module of the first embodiment;

FIG. 3B is a cross sectional view for describing the mounted state of the RF module of the first embodiment;

FIG. 4A is a plane view for describing the second embodiment of the present invention;

FIG. 4B is a cross sectional view taken along line B-B of FIG. 4A for describing the second embodiment;

FIG. 5A is a plane view for describing the third embodiment of the present invention;

FIG. 5B is a cross sectional view taken along line B-B of FIG. 5A for describing the third embodiment;

FIG. 6A is a plane view for describing the fourth embodiment of the present invention; and

FIG. 6B is a cross sectional view taken along line B-B of FIG. 6A for describing the fourth embodiment.

### DETAILED DESCRIPTION OF THE PREFERRED EMBODIMENTS

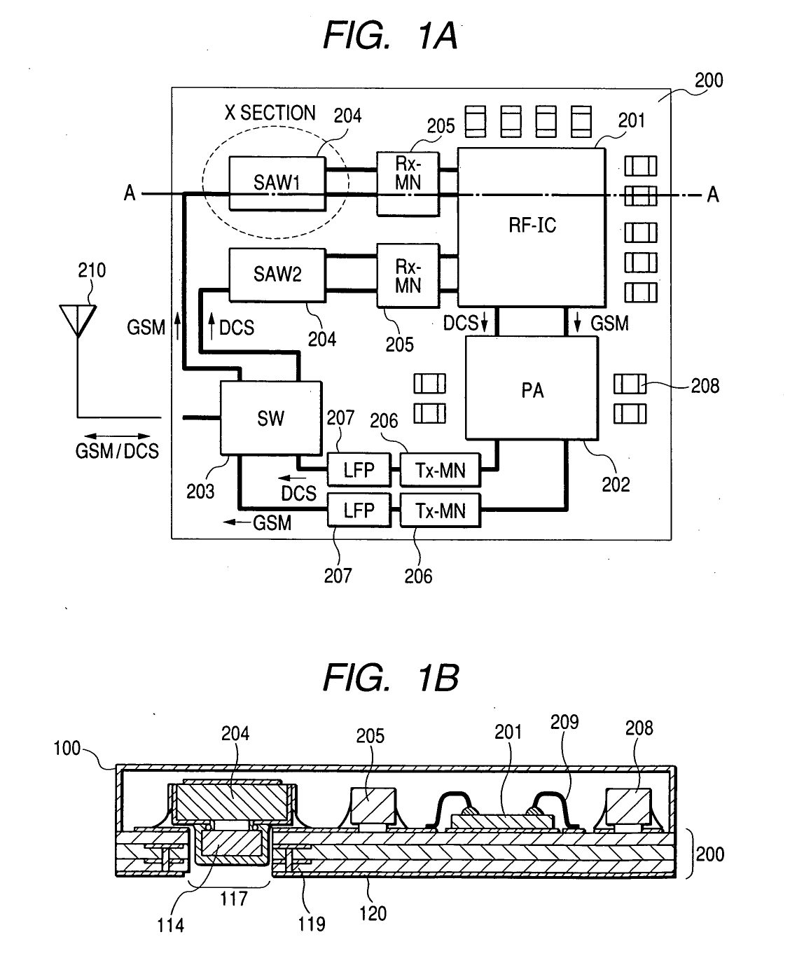

The RF module of the present invention is described next in detail while referring to the embodiments shown in the accompanying drawings. Identical reference numerals in FIG. 1A, FIG. 1B through FIG. 6A, 6B indicate the same item or similar item.

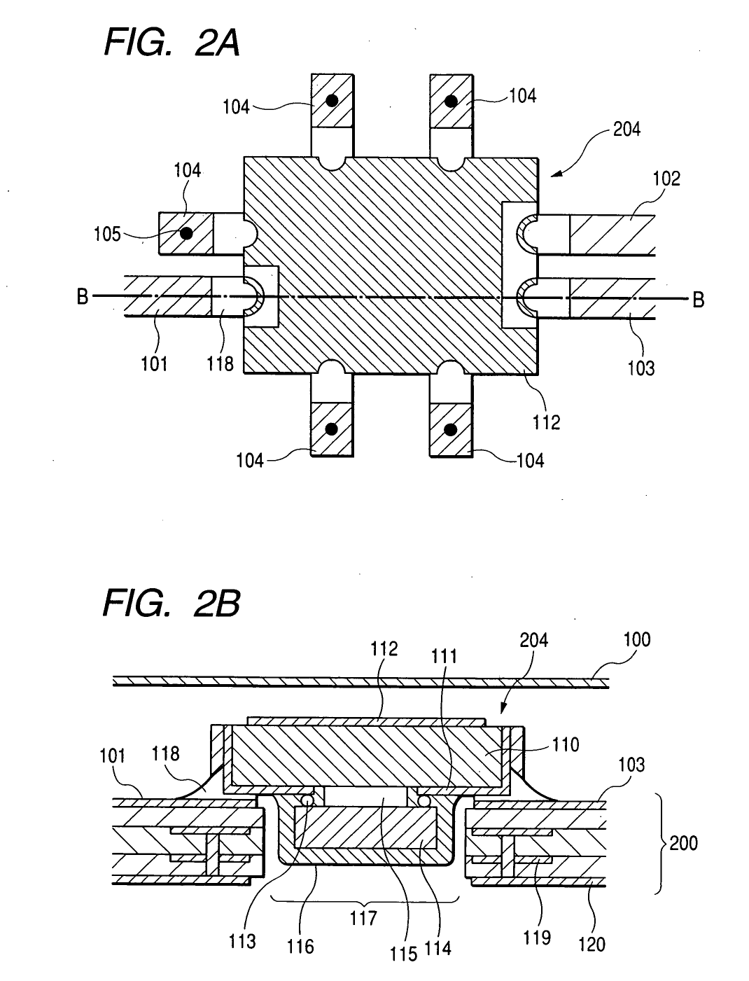

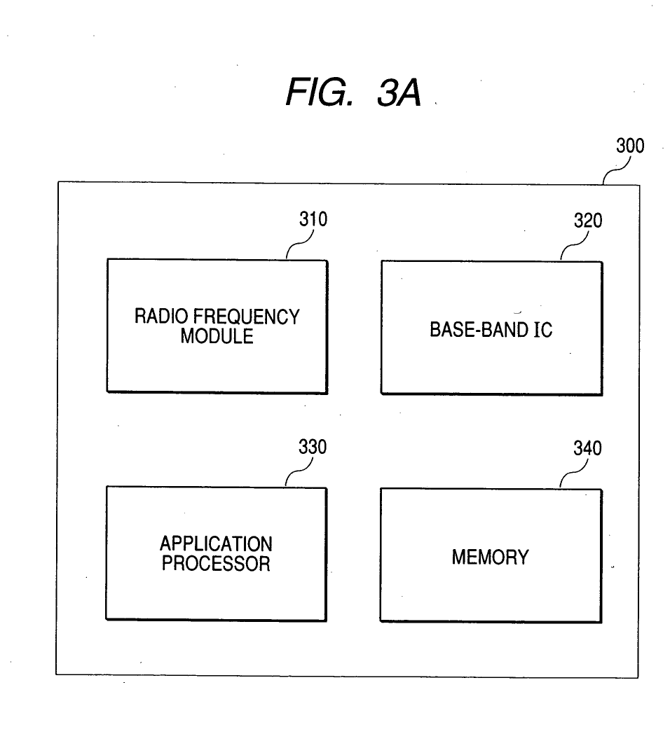

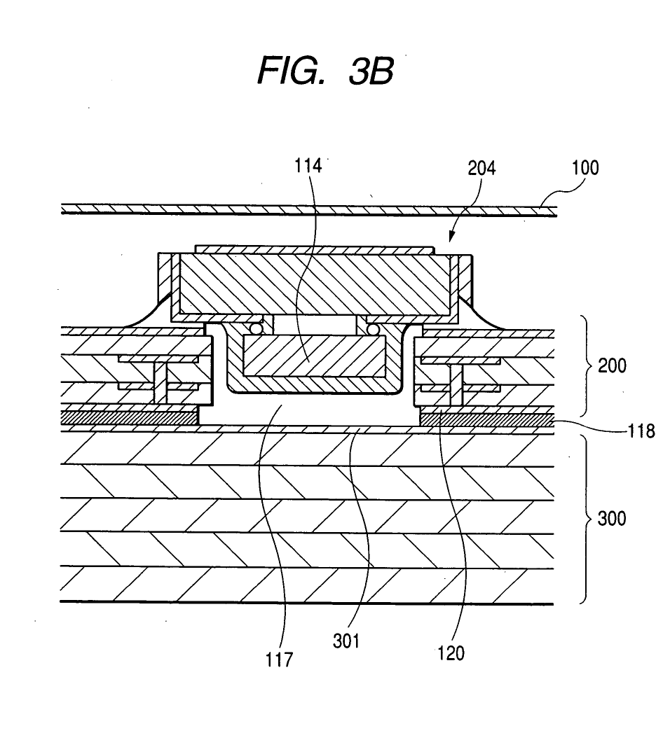

The first embodiment of the present invention is described next while referring to FIG. 1A, 1B, FIG. 2A, 2B and FIG. 3A, 3B. FIG. 1A is a block diagram of the RF module of the present invention. FIG. 1B is a cross sectional view taken along line A-A of FIG. 1A. As shown in FIG. 1A, the electronic components, RF-IC201, PA202, SW203, SAW package 204, matching circuit 205, and the chip components (capacitor, resistor, inductor) 208 for conveying the RF signal are mounted on the upper surface of the module substrate 200. The entire upper surface of the RF module is normally covered with a metal cap or sealed in a resin mold. However, these are omitted in FIG. 1A in order to describe the internal structure. Usually a large number of wires connect the terminals and each electronic component; however these drawings show only the RF line between the electronic components. The RF circuit line may be formed on the upper (uppermost surface) surface of the module substrate 200, or may be formed in an inner layer. The terminals (not shown) formed on the rear side of the module are for input and output of signals and the power supply for this module.

The RF module of the present embodiment is a unified RF module on which are integrated a dual-band cellular terminal RF section compatible with both the GSM system on the 800 MHz band and the DCS system on the 1800 MHz band. The baseband signal input to this module is converted to a GSM or a DCS band signal by the RF-IC201 and amplified in PA202. The signal next passes through the matching circuit 206 for matching the electronic components, the low pass filter 207 for attenuating the harmonic wave, and the switch SW203 by way of the SP4T type HEMT switch and is output from the module and finally transmitted from the antenna 210. The signal received from the antenna 210, passes through the switch SW203, interfering waves are removed in the SAW package 204. Next after passing through the matching circuit 205, the signal is converted to a baseband signal by the RF-IC 201 and output from the module. The chip component 208 is utilized to constitute electronic components such as the power supply circuit and control circuit.

In this module as shown in FIG. 1B, the module substrate 200 is a multi-layered organic laminate made up of three organic laminates. The SAW package 204 with its hermetically sealed structure, the matching circuit 205 comprised of the chip components, the chip component 208 and the RF-IC device 201 incorporating a send/receive function are mounted on the upper surface of the module substrate 200. The RF-IC device 201 is mounted on a bare chip and connected to the wirings on the substrate 200 by bonding wire 209, etc. Though described later on, the grounded conductors 119, 120 are formed on the inner layer or the rear surface in the vicinity of the throughhole 117.

Along with filtering out the desired frequency components, the SAW filter 114 within the SAW package 204 contains a balun function to convert the signal from a single-ended signal to a differential signal. A section of the SAW package 204 is inserted into the throughhole 117 and mounted. The SAW package 204 is at this time inserted into the throughhole 117 while inverted to face upside down compared to conventional mounting. The surface of the SAW package 204 that is nearer the SAW filter 114, or in other words the upper surface of the SAW package 204 is therefore installed at a lower position than the upper surface of the substrate 200.

Though not shown in the cross sectional view of FIG. 1B, the PA device 202 and the switch device 203 are also mounted on the bare chip on the upper surface of the substrate 200. The PA device 202 and the switch device 203 are connected to the wiring layer on the substrate 200 with bonding wire, etc.

An enlarged plane view of the X section of FIG. 1A is shown in FIG. 2A, and a cross sectional view along B-B in that figure is shown in FIG. 2B, in order to describe the SAW package 204 on the RF module of the present embodiment in detail. The metal cap covering the entire upper surface of the RF module is not shown in the plane view of FIG. 2A in order to show the internal section of the RF module. However, that metal cap is shown in FIG. 2B.

In FIG. 2A, the RF signal conveyed on the RF line 101 of the multi-layered organic laminate 200 is input to the SAW package 204. The desired frequency is then filtered and simultaneously converted to a differential signal, and is output to the differential signal lines 102, 103 on the substrate 200. The other electrodes 104 on the substrate 200 are all grounded terminals and are connected by the via hole 105 to the module ground.

The SAW package 204 used in the present embodiment is a hollow hermetically sealed package sealed by resin. A SAW filter 114 is mounted in flip-chip style with the metallic bump 113 on the ceramic substrate 110 that forms the ground conductor 112, and an electrode 111 mounted on both surfaces and the side surface of the package 204. The SAW filter 114 is then sealed by the resin 116. A space 115 is formed on the comb-shaped electrode of the SAW filter 114 so that the SAW filter will function correctly. The SAW package 204 is prefabricated separately.

In the RF module of the present invention, a throughhole 117 is formed in the resin multi-layered substrate 200, and the resin sealed section of the separately fabricated SAW package 204 is inserted in this throughhole. The SAW package 204 is fixed by the solder 118, and electrical connections are made simultaneously.

Compared to the method for mounting the SAW package 204 on the substrate in the method of the related art, the mounting method of the embodiment that inserts a section of the SAW package 204 into a section of the throughhole 117 can decrease the height of the RF module by an amount equal to the insertion distance. In the present embodiment, a section of the SAW filter is inserted into the throughhole 117 so the height of the RF module can be lowered by an amount (approximately 0.3 mm) equal to that insertion. The RF module mounted with the SAW package can therefore have a low profile in the present invention.

The throughhole 117 of the organic laminate 200 can be easily formed by a router or drill in the final substrate manufacturing process. The cost can therefore be substantially reduced compared to the method for forming a depression or cavity in the substrate (in other words, removing a portion of the substrate).

By inserting the SAW package 204 into the throughhole 117 facing opposite conventional mounting direction, the present invention allows making the electrical connections on the upper substrate surface outside the throughhole and allows easily making these electrical connections. The connections in the present embodiment can be made using solder and can be mounted by a process comprised of cream-solder printing, component mounting and reflow soldering, the same as for the other chip components. An electrode is formed on the side surface of this package 204 in order to form a solder fillet to increase the strength of the connection, and to allow inspecting the solder connection visually. This electrode might not always be necessary in the embodiments of the invention.

In the present embodiment, the comb-shaped electrode of the SAW filter 114 can be shielded from electromagnetic noise from the upper side by connecting a ground connector 112 formed on the ceramic substrate 110 of the SAW package 204, to the RF module ground. The SAW package 204 that is resin-sealed may sometimes be affected by noise since the SAW filter 114 side is only sealed by resin. In such cases, forming grounding connectors 119, 120 on the inner layer and rear surface of the vicinity of the throughhole 117 of the multi-layered substrate 200 will reduce the noise affect effectively. The grounding connectors 119, 120 function to shield the periphery of the SAW filter 114.

The present invention therefore is capable of providing high resistance to electromagnetic noise even when utilizing the resin-sealed SAW package. In other words, by mounting the SAW package 204 in the throughhole 117 to face in the reverse direction of the related art, even more effective shielding can be provided for the SAW filter 114 when the RF module is mounted on the motherboard of the wireless communication device.

FIG. 3A shows a upper plane view of the motherboard 300 on which the RF module 310 of the present embodiment is mounted. The motherboard 300 is a circuit board for the cellular telephone and therefore besides the RF module 310, a baseband IC320 for processing baseband signals, and a memory 340 for storing data and programs, and an application processor 330 for executing functions such as the cellular telephone and mail send/receive functions are all contained on the motherboard 330.

FIG. 3B is a cross sectional view for showing a section of the SAW package 204 of the RF module 310. A ground conductor 301 is formed also in the section directly below the throughhole 117 of the substrate 300. The ground conductor 301 and the ground conductor 120 on the rear side of the multi-layered substrate 200 are connected by the solder 118. Forming these ground conductors 301, shields the front surface of the SAW filter 204 and boosts the EMC (electromagnetic compatibility or resistance to electromagnetic noise) when this RF module is mounted on the circuit board of a wireless communication device such a cellular telephone.

The RF module of the present embodiment as described above is a unified RF module on which is integrated the all RF section of a cellular telephone. Needless to say, the present invention is not limited to this type of module and may be applied to all general wireless communication modules on which SAW packages are mounted such as antenna switch modules on which SAW filters and RF switches are integrated, or receive modules on which are integrated receive circuits for converting the received signals into baseband signals, and SAW filters, receive matching circuits. Moreover, the wireless communication device of the present invention is not limited to cellular telephones and may be a transmitter-receiver device for wireless LAN (Local Area Network) having an operating frequency of 2 through 60 GHz, or a transceiver using frequencies of 26 through 27 MHz. The motherboard 300 is one example of a circuit board utilized in that type of wireless communication device. The RF range of the present invention is a range from several dozen MHz to several dozen GHz.

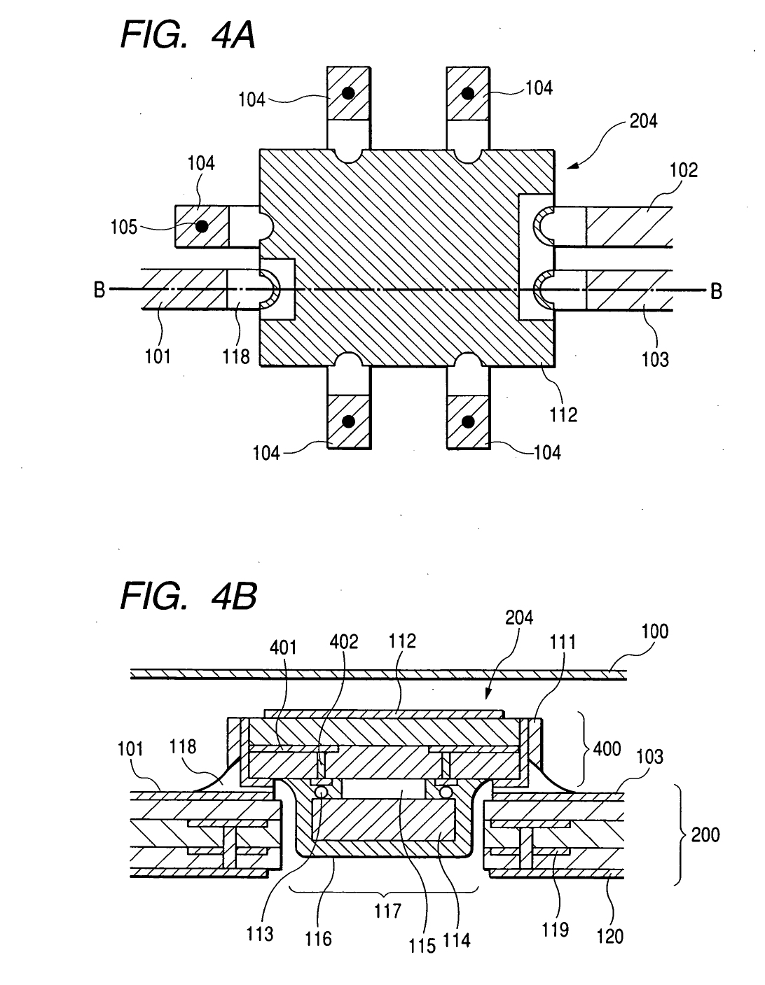

The second embodiment of the present invention is described next while referring to FIG. 4A and FIG. 4B. FIG. 4A is a plane view showing the section on which the SAW package 204 of the RF module of the present invention is mounted. FIG. 4B is a cross sectional view taken along lines B-B of FIG. 4A. In order to show the internal sections, the FIG. 4A does not show the metallic cap 100 installed on the RF module upper surface. Aside from the following points, the RF module of the present embodiment and related equipment are identical to the first embodiment. The module is for example the RF unified module of FIG. 1A and FIG. 1B.

The points where the present embodiment differs from the first embodiment is that the substrate 400 on which the SAW114 is flip-chip mounted is a ceramic multi-layered substrate and contains an internal layer wiring path 401 and a via hole 402 inside. The present embodiment therefore has more freedom for internal wiring within the ceramic substrate 400. For example, a matching circuit such as an inductor and condenser can be formed within the ceramic substrate 400. The other structural elements are identical to the first embodiment so their description is omitted here.

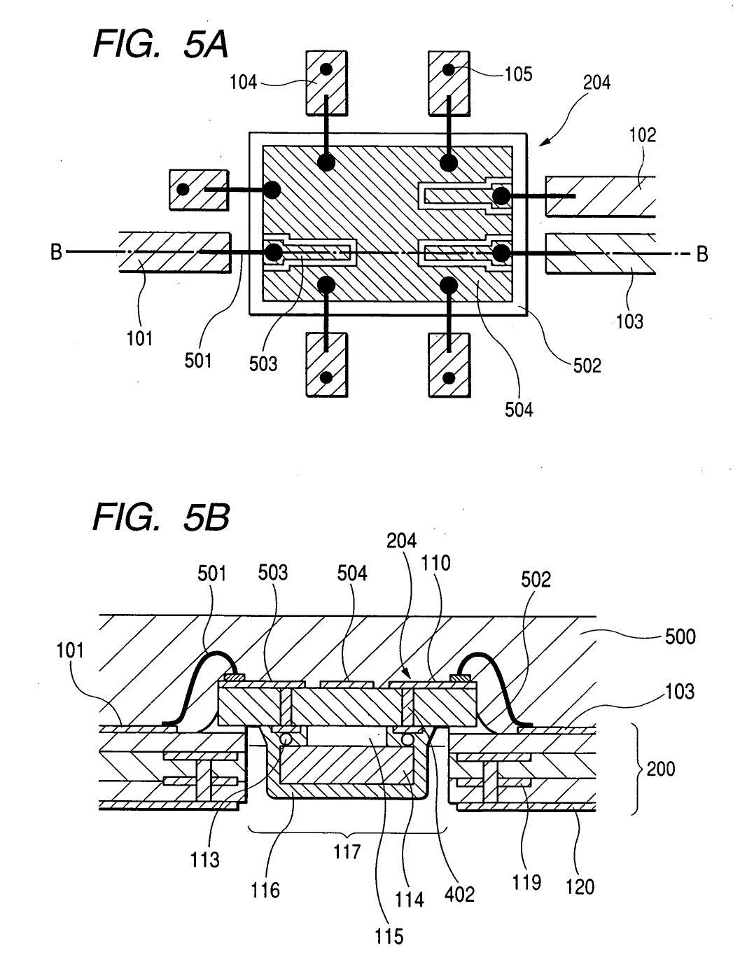

The third embodiment of the present invention is described next while referring to FIG. 5A and FIG. 5B. FIG. 5A is a plane view showing the section on which the SAW package 204 of the RF module of the present invention is mounted. FIG. 5B is a cross sectional view taken along lines A-A of FIG. 5A. In order to show the internal sections, the sealing resin 500 formed over the entire surface of the RF module is omitted. Aside from the following points, the RF module of the present embodiment and related equipment are identical to the first embodiment. The module is for example the RF unified module of FIG. 1A and FIG. 1B.

The present embodiment differs from the first and second embodiments in the point that the bonding wire 501 is utilized to connect the SAW package 204 with the module substrate 200. The separately fabricated SAW package 204 is inserted into the throughhole 117 of the module of the multi-layered organic laminate 200, and fixed with adhesive 502. Next, the electrode 503 of the SAW package 204 connected to the via hole 402 and the wire paths 101 through 103 of the multi-layered organic laminate 200, and the grounding conductor 504 and the electrode 104 of the multi-layered organic laminate 200 are connected by the bonding wire 501. This module is then fabricated by injection molding of the epoxy resin 500 onto the upper surface of the substrate 200.

In the structure of the present module, no high temperatures or pressure are applied to the resin 116 sealing the SAW filter 114 during the injection molding. The occurrence of problems such as the softening of the resin 116 and destruction of sealing or the crushing of the hollow structure 115, or the SAW filter 114 separating from the metallic bump can therefore be prevented. Namely, defects in the process for making a resin mold of the module substrate can be prevented.

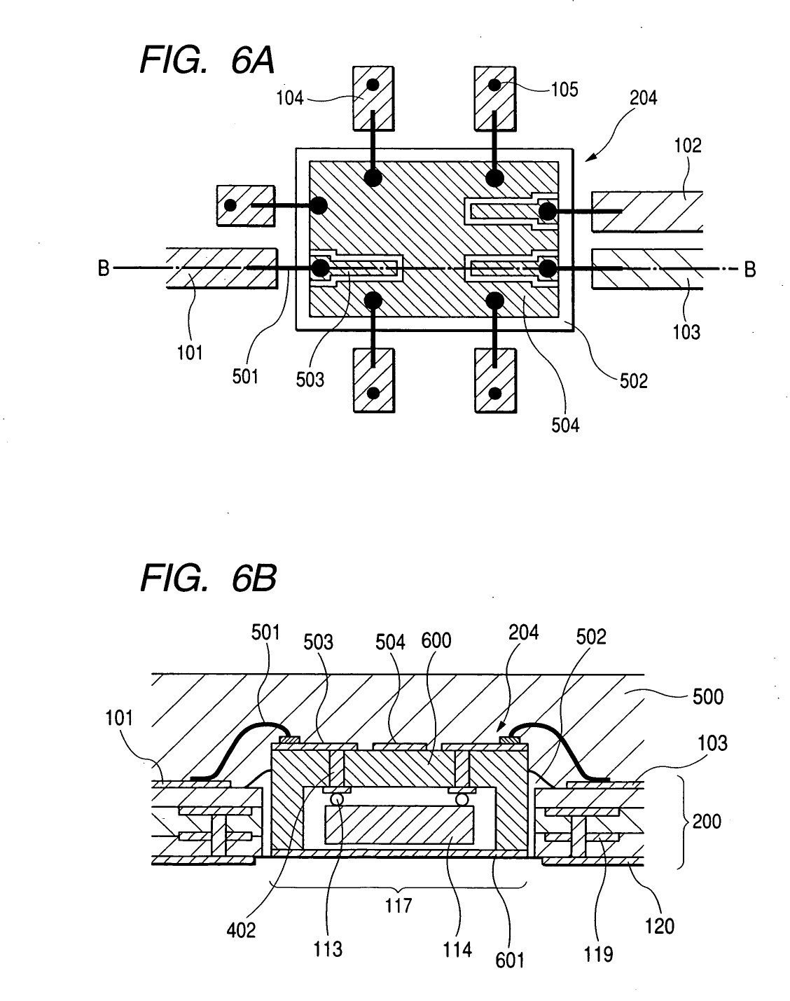

The fourth embodiment of the present invention is described next while referring to FIG. 6A and FIG. 6B. FIG. 6A is a plane view showing the section where the SAW package 204 of the RF module of the present invention is mounted. FIG. 6B is a cross sectional view taken along line A-A of FIG. 6A. In order to show the internal sections, the sealing resin 500 formed over the entire surface of the RF module is omitted. Aside from the following points, the RF module of the present embodiment and related equipment are identical to the first embodiment. The module is for example the unified RF module of FIG. 1A and FIG. 1B.

The SAW package 204 utilized in the present embodiment differs from other embodiments in that it is a ceramic hermetically sealed package. In this SAW package, the SAW filter 114 is flip-chip mounted on the multi-layered ceramic substrate having a cavity structure, by utilizing the metallic bumps 113. The metal cap 601 is fixed by AuSn (gold/tin) solder. The cost of this ceramic hermetically sealed package type SAW package 204 is high compared to the resin sealed type but has higher reliability.

The RF module of this embodiment is manufactured as follows. The separately fabricated SAW package 204 is inserted into the throughhole 117 of the resin multi-layered substrate 200 of the RF module and fixed with adhesive 502. Next, the electrode 503 on the rear side of the SAW package 204, and the wire paths 101 through 103 of the module substrate 200, as well as the grounding conductor 504 and the electrode 104 of the module substrate 200 are connected by the bonding wire 501. The entire upper surface of the substrate 200 is then sealed by injection molding of the epoxy resin 500. The overall reliability of the module is in this way increased.

As shown in FIG. 6B, on the ceramic substrate 600, the section of the SAW package 204 of the present embodiment installed inside the throughhole has approximately the same outer cross sectional shape as the portion outside the throughhole.

In this case, though not shown in the drawing, a protruding structure can be formed on the side surface of the SAW package 204 covered with the adhesive 502. This protruding structure prevents problems such as the SAW package 204 coming out of the throughhole 117 from changes over the passage of time due to the operating environment.

When the thickness of the SAW package 204 (distance between the electrode 503 making up the rear surface of the package 204, and the metal cap making up the surface of the package 204) is smaller than the thickness of the multi-layered substrate 200, then the package 204 can be mounted so that the surface forming the rear side of the package 204 matches the surface forming the upper side of the module substrate 200. By inserting approximately the entire SAW package 204 into the throughhole 117, the SAW filter 114 can be isolated to a greater extent from the upper surface of the module substrate 200 where the other electronic components are mounted and in this way higher resistance to electromagnetic noise (or EMC: electromagnetic compatibility) can be achieved.

The description in the first through the fourth embodiments explained in particular the case where the module substrate was a multi-layered organic laminate. However, the embodiments may also be implemented in the same way with a single organic laminate.

1. A radio frequency module comprising at least a module substrate including at least one layer, and a sealed package that encloses surface-acoustic-wave filter, wherein
the module substrate contains a throughhole, and
the package is mounted on the module substrate so that at least a part of the package is installed in the throughhole.

2. A radio frequency module according to claim 1, wherein the module substrate is organic laminate.

3. A radio frequency module according to claim 1, wherein the package includes a structure for mounting the surface-acoustic-wave filter as a flip-chip on the ceramic substrate of a least one layer formed with an electrode for connecting the surface-acoustic-wave filter; and a part of the ceramic substrate section and a part of the electrode formed on the ceramic substrate are mounted so as to be disposed outside the throughhole.

4. A radio frequency module according to claim 3, wherein the width of at least one side of the ceramic substrate is larger than the width of the throughhole, and the package is mounted so the ceramic substrate is positioned mostly outside the throughhole, and the surface-acoustic-wave filter is positioned mostly inside the throughhole.

5. A radio frequency module according to claim 4, wherein the wiring path formed on the upper surface of the module substrate, and the electrode formed on the ceramic substrate of the package are connected by solder.

6. A radio frequency module according to claim 3, wherein the electrode formed on the upper surface of the module 5 substrate, and the electrode formed on the ceramic substrate of the package are connected by bonding wire.

7. A radio frequency module according to claim 3, wherein the ceramic substrate for the package is fixed by adhesive to the module substrate.

8. A radio frequency module according to claim 7, wherein the outer cross sectional shape of the part of the ceramic substrate for the package disposed inside the throughhole is approximately the same as that disposed outside the throughhole.

9. A radio frequency module according to claim 8, wherein the ceramic substrate for the package is further formed with a protrusion on the part disposed in the throughhole.

10. A radio frequency module according to claim 7, wherein in addition to the package, at least one electronic component selected from a group including a switch device, a power amplifier device, and a transceiver IC is mounted on the upper surface of the module substrate.

11. A radio frequency module according to claim 10, wherein a resin mold is applied to cover the package and the electronic components mounted on the upper surface of the module substrate.

12. A radio frequency module according to claim 1, wherein in addition to the package, at least one electronic component selected from a group including a switch device, a power amplifier device, and a transceiver IC is mounted on the upper surface of the module substrate.

13. A radio frequency module according to claim 12, wherein a resin mold is applied to cover the package and the electronic components mounted on the upper surface of the module substrate.

14. A radio frequency module according to claim 12, wherein the package and the electronic components mounted on the upper surface of the module substrate are covered by a metal cap.

15. A radio frequency module according to claim 1, wherein a ground conductor is formed on the rear side or the inner layer of the module substrate in the vicinity of the throughhole.

16. A circuit board for a wireless communication device mounted with at least the radio frequency module of claim 1, wherein the ground conductor is formed in the vicinity of the throughhole of the module substrate to cover the throughhole.

17. A radio frequency module comprising:
a first substrate with at least one layer, of which upper surface is a component side; and
at least a sealed package that encloses a surface-acoustic-wave filter mounted on at least one layer of the second substrate,
wherein the first substrate includes a throughhole, and
the surface of the package is the side for mounting the surface-acoustic-wave filter, and
the surface of the package within the throughhole is mounted on the first substrate at a position lower than the upper surface of the first substrate.
